(19) United States
(12) Patent Application Publication
(10) Pub. No.: US 2026/0024561 A1
(43) Pub. Date: Jan. 22, 2026

(54) LOCAL INTERCONNECT DIGIT LINE INTERFACE

(71) Applicant: Micron Technology, Inc., Boise, ID (US)

(72) Inventors: Inchan Hwang, Boise, ID (US); Russell A. Benson, Boise, ID (US); Vinay Nair, Boise, ID (US)

(21) Appl. No.: 19/268,328

(22) Filed: Jul. 14, 2025

Related U.S. Application Data
(60) Provisional application No. 63/673,435, filed on Jul. 19, 2024.

(51) Int. Cl. G11C 5/06; G11C 11/4091; H10B 12/00

(52) U.S. Cl. CPC G11C 5/063; G11C 11/4091; H10B 12/482; H10B 12/485; H10B 12/50

(57) ABSTRACT

The present disclosure includes apparatuses and methods for local interconnect digit line interfaces. An example apparatus includes an array of memory cells. Each memory cell of array of memory cells can be coupled to a digit line and a first spacer can separate a first portion of the digit line from a second portion of the digit line. A local interconnect digit line interface can be located at the first portion of the digit line and the first portion of the digit line can be electrically coupled to a sense amplifier via the local interconnect digit line interface and the second portion of the digit line cannot be electrically coupled to the sense amplifier.

### PRIORITY INFORMATION

This application claims the benefits of U.S. Provisional Application 63/673,435, filed on Jul. 19, 2024, the contents of which are incorporated herein by reference.

### TECHNICAL FIELD

The present disclosure relates generally to semiconductor memory and methods, and more particularly, to apparatuses and methods for local interconnect digit line interfaces in memory arrays.

### BACKGROUND

Memory devices are typically provided as internal, semiconductor, integrated circuits in computers or other electronic systems. There are many different types of memory including volatile and non-volatile memory. Volatile memory can require power to maintain its data (e.g., host data, error data, etc.) and includes random access memory (RAM), dynamic random access memory (DRAM), static random access memory (SRAM), synchronous dynamic random access memory (SDRAM), and thyristor random access memory (TRAM), among others. Non-volatile memory can provide persistent data by retaining stored data when not powered and can include NAND flash memory, NOR flash memory, and resistance variable memory such as phase change random access memory (PCRAM), resistive random access memory (RRAM), and magnetoresistive random access memory (MRAM), such as spin torque transfer random access memory (STT RAM), among others.

Electronic systems often include a number of processing resources (e.g., one or more processors), which may retrieve and execute instructions and store the results of the executed instructions to a suitable location. A processor can comprise a number of functional units such as arithmetic logic unit (ALU) circuitry, floating point unit (FPU) circuitry, and a combinatorial logic block, for example, which can be used to execute instructions by performing an operation on data (e.g., one or more operands). As used herein, an operation can be, for example, a Boolean operation, such as AND, OR, NOT, NOT, NAND, NOR, and XOR, and/or other operations (e.g., invert, shift, arithmetic, statistics, among many other possible operations). For example, functional unit circuitry may be used to perform the arithmetic operations, such as addition, subtraction, multiplication, and division on operands, via a number of operations.

### BRIEF DESCRIPTION OF THE DRAWINGS

FIG. 1A is an illustration of an array of memory cells having a folded digit line architecture in accordance with a number of embodiments of the present disclosure.

FIG. 1B is an illustration of an array of memory cells having an open digit line architecture.

FIG. 2 illustrates a cross-section of a portion of a memory cell array in accordance with a number of embodiments of the present disclosure.

FIG. 3 is a top view of an array of memory cells having a folded digit line sense amplifier architecture in accordance with a number of embodiments of the present disclosure.

FIG. 4 is an isometric view of portion of a memory die including an array region, an isolation region, and a peripheral component region in accordance with a number of embodiments of the present disclosure.

FIGS. 5-7 illustrate an example method, at another stage of semiconductor fabrication process, for forming a digit line in an isolation region of a memory die in accordance with a number of embodiments of the present disclosure.

FIG. 8 illustrates a local interconnect digit line interface in an isolation region of a memory die in accordance with a number of embodiments of the present disclosure.

FIG. 9 is a block diagram of an apparatus in the form of a computing system including a memory device in accordance with a number of embodiments of the present disclosure.

### DETAILED DESCRIPTION

The present disclosure includes apparatuses and methods for local interconnect digit line interfaces. An example apparatus includes an array of memory cells. Each memory cell of array of memory cells can be coupled to a digit line and a spacer can separate a first portion of the digit line from a second portion of the digit line. A local interconnect digit line interface can be located at the first portion of the digit line, where the spacer prevents erosion of the second portion of the digit line from reaching the first portion of the digit line that includes the local interconnect digit line interface.

In the following detailed description of the present disclosure, reference is made to the accompanying drawings that form a part hereof, and in which is shown by way of illustration how one or more embodiments of the disclosure may be practiced. These embodiments are described in sufficient detail to enable those of ordinary skill in the art to practice the embodiments of this disclosure, and it is to be understood that other embodiments may be utilized and that process, electrical, and structural changes may be made without departing from the scope of the present disclosure.

As used herein, designators such as “X”, “Y”, “N”, “M”, etc., particularly with respect to reference numerals in the drawings, indicate that a number of the particular feature so designated can be included. It is also to be understood that the terminology used herein is for the purpose of describing particular embodiments only, and is not intended to be limiting. As used herein, the singular forms “a”, “an”, and “the” can include both singular and plural referents, unless the context clearly dictates otherwise. In addition, “a number of”, “at least one”, and “one or more” (e.g., a number of memory arrays) can refer to one or more memory arrays, whereas a “plurality of” is intended to refer to more than one of such things. Furthermore, the words “can” and “may” are used throughout this application in a permissive sense (i.e., having the potential to, being able to), not in a mandatory sense (i.e., must). The term “include,” and derivations thereof, means “including, but not limited to”. The terms “coupled” and “coupling” mean to be directly or indirectly connected physically or for access to and movement (transmission) of commands and/or data, as appropriate to the context. The terms “data” and “data values” are used interchangeably herein and can have the same meaning, as appropriate to the context.

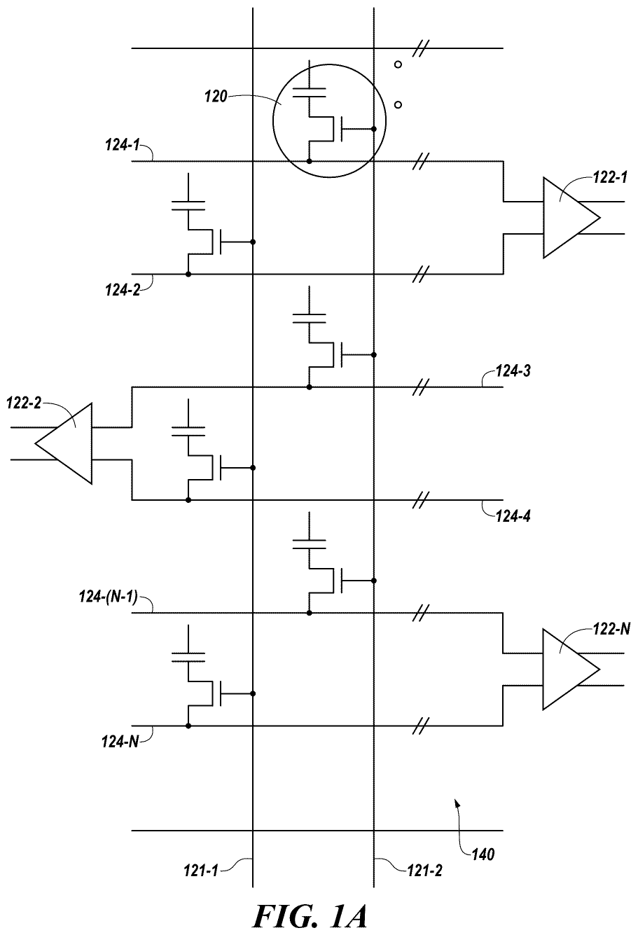

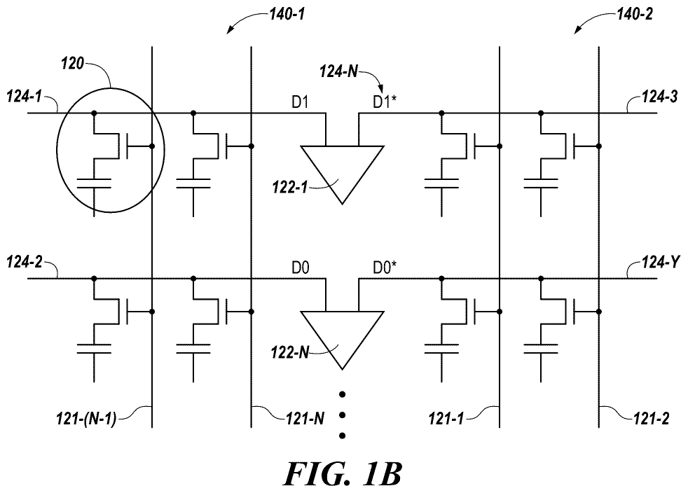

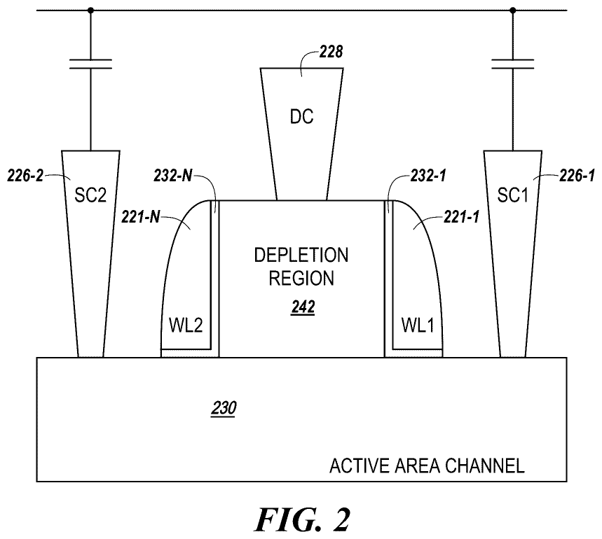

The figures herein follow a numbering convention in which the first digit or digits correspond to the figure number and the remaining digits identify an element or component in the figure. Similar elements or components between different figures may be identified by the use of similar digits. For example, 121 may reference element “21” in FIG. 1A, and a similar element may be referenced as 221 in FIG. 2. As will be appreciated, elements shown in the various embodiments herein can be added, exchanged, and/or eliminated so as to provide a number of additional embodiments of the present disclosure. In addition, the proportion and/or the relative scale of the elements provided in the figures are intended to illustrate certain embodiments of the present disclosure and should not be taken in a limiting sense.

FIG. 1A is an illustration of an array of memory cells having a folded digit line architecture in accordance with a number of embodiments of the present disclosure. In FIG. 1A, an array of memory cells includes a number of memory cells 120, each including a storage container shown as a capacitor in FIG. 1A and an access device shown in as a transistor in FIG. 1A, in a folded digit line architecture. The array of memory cells 140 includes access lines 121-1 and 121-2 coupled to gates of the memory cells and digit lines 124-1, 124-2, 124-3, 124-4, 124-(N-1), and 124-N coupled to source/drain regions of the access devices of the memory cells. Each pair of digit lines are coupled to a sense amplifier in a folded digit line architecture, where digit lines 124-1 and 124-2 are coupled to sense amplifier 122-1, digit lines 124-3 and 124-4 are coupled to sense amplifier 122-2, and digit lines 124-(N-1) and 124-N are coupled to sense amplifier 122-N.

The array of memory cells 140 is configured such that each access line 121-1 and 121-2 is coupled to memory cells that are coupled to every other digit line. For example, access line 121-1 is coupled to memory cells that are coupled to digit lines 124-2, 124-4, and 124-N and access line 121-2 is coupled to memory cells that are coupled to digit lines 124-1, 124-3, and 124-(N-1). This configuration allows, in the folded digit line architecture, for adjacent digit lines to be the reference signal when sensing memory cells in the array of memory cells 140. For example, when sensing the memory cell coupled to digit line 124-1 and access line 121-2, the digit line 124-2 can provide the reference signal to sense amp 122-1, due to digit line 124-2 not be coupled to a memory cell on access line 121-2.

FIG. 1B is an illustration of arrays of memory cells having an open digit line architecture. In FIG. 1B, arrays of memory cells 140-1 and 140-2 include a number of memory cells 120, each including a storage container shown as a capacitor in FIG. 1B and an access device shown in as a transistor in FIG. 1B, in an open digit line architecture. The array of memory cells 140-1 includes access lines 121-N and 121-(N-1) coupled to gates of the memory cells and digit lines 124-1 and 124-2 coupled to source/drain regions of the access devices of the memory cells. The array of memory cells 140-2 includes access lines 121-1 and 121-2 coupled to gates of the memory cells and digit lines 124-3 and 124-Y coupled to source/drain regions of the access devices of the memory cells. In an open digit line architecture, each digit line is coupled to each memory cell in a row and each sense amplifier is coupled to a digit line from adjacent arrays of memory cells. For example, sense amplifier 122-1 is coupled to digit line 124-1 in array 140-1 and digit line 124-3 in array 140-2 and sense amplifier 122-N is coupled to digit line 124-2 in array 140-1 and digit line 124-Y in array 140-2.

In the open digit line architecture in FIG. 1B, when sensing memory cells in the array 140-1 the reference signal is from array 140-2; and when sensing memory cells in the array 140-2 the reference signal is from array 140-1. For example, when sensing the memory cells coupled to digit line 124-1 in array 140-1, digit line 124-3 can provide the reference signal to sense amp 122-1.

FIG. 2 illustrates a cross-section of a portion of an array of memory cells in accordance with a number of embodiments of the present disclosure. FIG. 2 shows vertically oriented access lines 221 (e.g., access line 221-1 and access line 221-N) each coupled to a respective pair of gate oxide 232 (e.g., gate oxide 232-1 and gate oxide 232-N). The vertically oriented access lines 221 may be analogous or similar to access lines 121 and 221 of FIGS. 1A and 1B and 2 respectively.

The vertically oriented access lines 221 may be formed on opposing sides of depletion region 242. A digit line contact 228 may be located adjacent the depletion region 242. For example, the digit line contact 228 may be located above the depletion region 242. The depletion region 242 may be flanked by the pair of vertically oriented access lines 221 and insulator 232 (e.g., a gate oxide) may be formed between the depletion region 242 and the vertically oriented access lines 221.

The gate oxide 232 may be vertically oriented above an active area 230 of the memory cell and on a sidewall of the depletion region 242 of the memory cell. Therefore, the gate 221 may also be vertically formed above the active area 230 of the memory cell and on a sidewall of the depletion region 242 of the memory cell. The gate may be connected to and/or formed from the vertically oriented access lines 221, on opposing sides of the depletion region 242. In FIG. 2, a first memory cell of the pair of memory cells includes storage container contact 226-1 and a storage container (e.g., capacitor, not shown) formed above the storage container contact 226-1. Each memory cell of the pair of memory cells includes an access device. Each pair of memory cells may share the digit line contact 228 that is coupled to the depletion region 242. A first memory cell includes a first access device comprising a gate formed of access line 221-1, an insulator 232-1, a first source/drain and a second source drain region separated by a channel region. The channel region of the first access device is formed in the active area 230 and depletion region 242 between the first source/drain coupled to the digit line contact 228 and the second source/drain coupled to the storage container contact 226-1. A second memory cell includes a second access device comprising a gate formed of access line 221-N, an insulator 232-N, a first source/drain and a second source drain region separated by a channel region. The channel region of the second access device is formed in the active area 230 and depletion region 242 between the first source/drain coupled to the digit line contact 228 and the second source/drain coupled to the storage container contact 226-2. The insulators 232-1 and 232-N may be formed opposing the channel region.

The vertically oriented access lines 221 and the gate may be formed (e.g., grown) using atomic layer deposition (ALD) techniques. The gate formed of access lines 221-1 and 221-N and insulators 232-1 and 232-N controls current flow between the digit line contact 228 and the storage container contacts 226-1 and 226-2. The insulators 232-1 and 232-N and access lines 221-1 and 221-N may be formed to a thin width to enable density and to a tall height to provide conductor volume to enable sufficient current flow. For example, the insulators 232-1 and 232-N and access lines 221-1 and 221-N may have an aspect ratio (AR) of the height to width being in a range of from 5:1 to 15:1.

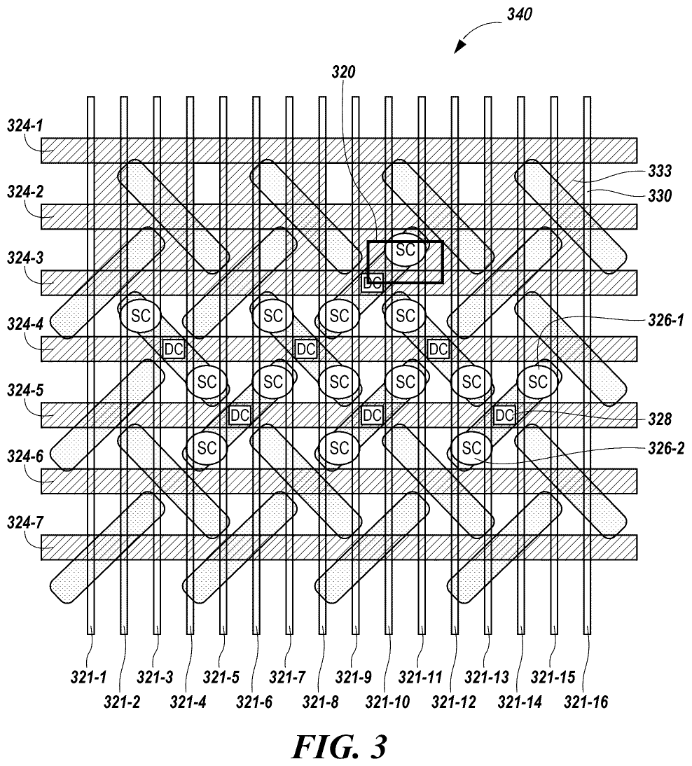

FIG. 3 is a top view of an array of memory cells having a folded digit line sense amplifier architecture in accordance with a number of embodiments of the present disclosure. The vertically oriented access lines 321 may be analogous or similar to access lines 121 and 321 of FIGS. 1A, 1, and 3 respectively. Digit lines 324 may be analogous or similar to digit lines 124 of FIGS. 1A and 1B. Memory cells 320 may be analogous or similar to memory cells 120 of FIGS. 1A and 1B. Storage container contact 326 may be analogous or similar to storage container contacts 226 of FIG. 2. Active area 330 may be analogous or similar to active area 230 of FIG. 2. Digit line contact 328 may be analogous or similar to digit line contact 228 of FIG. 2.

In this embodiment, the memory array 340 is a DRAM array of 1T1B (one transistor one capacitor) memory cells, although other embodiments of configurations can be used (e.g., 2T2C with two transistors and two capacitors per memory cell). In the array of memory cells illustrated in FIG. 3, the memory cells 320 includes an active area 330. In the embodiment illustrated, each active area 330 contains a pair of access devices that share a digit line contact 328.

Each access device of the pair of access devices may have a first source/drain region and a second source drain region separated by a channel region. The gate may be formed opposing the channel region. Adjacent memory cells share a digit line contact at the second source/drain region and a storage node contact 326 coupled to each first source/drain region. An insulator material 333 may be formed in between adjacent digit lines to isolate adjacent memory cells. The insulator material 333 may be formed to protect the vertically oriented access lines 321 from leaking current between adjacent cells. The leak may occur through a shared depletion region (e.g., depletion region 242 as described in FIG. 2).

The digit lines 324 may be coupled to a sense amplifier according to a folded digit line sense amplifier architecture. For example, the memory cell is coupled to the digit line 324 having a folded digit line sense amplifier architecture. As such, each vertically oriented access line 321 may pass over alternating active areas so that only every other digit line 324 is activated while adjacent digit lines remain at a reference voltage. For example, vertically oriented access line 321-4 may pass over alternate active areas than vertically oriented access line 321-5. Each vertically oriented access line 321 may activate one memory cell of the pair of adjacent memory cells while adjacent memory cells are kept at a reference voltage. The activated memory cell and the reference memory cell are within the same subarray to reduce signal-to-noise ratio and provide better sensing ability.

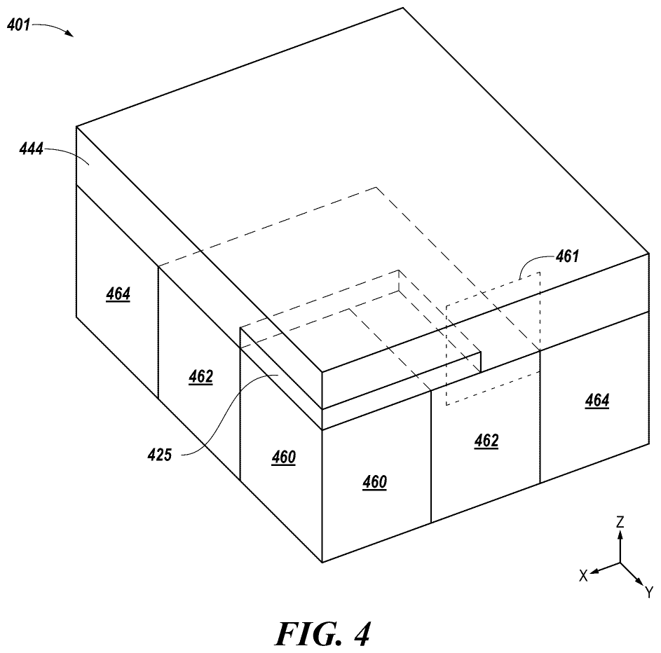

FIG. 4 is an isometric view of portion of a memory die including an array region, an isolation region, and a peripheral component region in accordance with a number of embodiments of the present disclosure. FIG. 4 illustrates an isometric view of portion of a memory die 401 at one stage of a semiconductor fabrication process when forming a local interconnect digit line interface.

Memory die 401 can include array region 460, where an array of memory cells, such as arrays of memory cells described in FIGS. 1A-3, can be located. Memory die 401 can include peripheral circuitry region 464, where CMOS logic circuitry, among other types of circuitry to access and control the array of memory cells, can be located. Memory die 401 can include isolation region 462 where a number of dielectric material portions can be formed to isolate the array region 460 from the peripheral circuitry region 464.

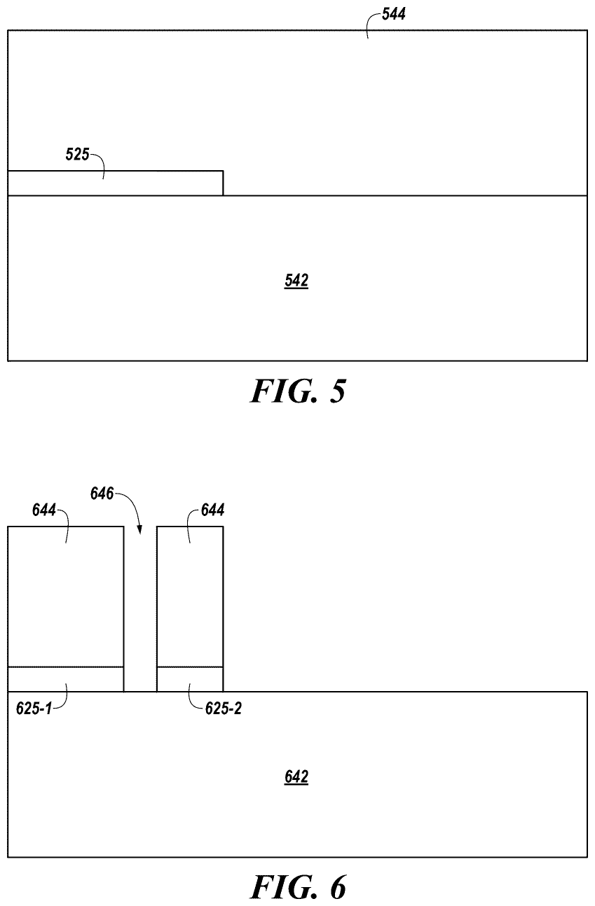

Memory die 401 can include conductive material 425 that is formed in the array region 460 and also in portion of the isolation region 462. Conductive material 425 can be further processed, as described in FIGS. 5-8, while forming digit lines for the array of memory cells. The digit lines can be part of local interconnect digit line interfaces that are formed in accordance with various embodiments of the present disclosure. Memory die 401 can include dielectric 444 that is formed in the array region 460, isolation region 462, and peripheral circuitry region 464. Dielectric material 444 can be further processed, as described in FIGS. 5-7, while forming digit lines for the array of memory cells.

FIGS. 5-7 illustrate an example method, at another stage of semiconductor fabrication process, for forming a digit line in an isolation region of a memory die in accordance with a number of embodiments of the present disclosure. FIGS. 5-7 illustrate a cross-section view in the x-z plane of portion 461 of the memory die illustrated in FIG. 4. Portion 461 is in the isolation region 462 of the memory die. FIG. 5 includes dielectric material 542 that forms a portion of the isolation region between the array region and the peripheral circuitry region, conductive material 525, and dielectric material 544. Dielectric material 542 can be an oxide and dielectric material 544 can be a nitride. Conductive material 525 can be further processed to act as a digit line for the array of memory cells and can be a conductive metal, such as tungsten, for example, among other conductive materials.

FIG. 6 illustrates a cross-section view in the x-z plane of portion 461 of the memory die illustrated in FIG. 4 after removing portions of the dielectric material. In FIG. 6, an etch process is used to remove portions of dielectric material and conductive material (e.g., portions of dielectric material 544 and conductive material 525 shown in FIG. 5) to form opening 646 and separate the conductive material into a first portion of conductive material 625-1 and a second portion of conductive material 625-2.

FIG. 7 illustrates a cross-section view in the x-z plane of portion 461 of the memory die illustrated in FIG. 4 after forming a dielectric material an opening (e.g., opening 646 illustrated in FIG. 6). In FIG. 7, deposition process is used to form dielectric material 748 on dielectric material portions 744, fill the opening (e.g., opening 646 illustrated in FIG. 6), and on dielectric material 742. Dielectric material 748 is formed between the first portion of conductive material 725-1 and the second portion of the conductive material 725-2. Dielectric material 748 can be a nitride.

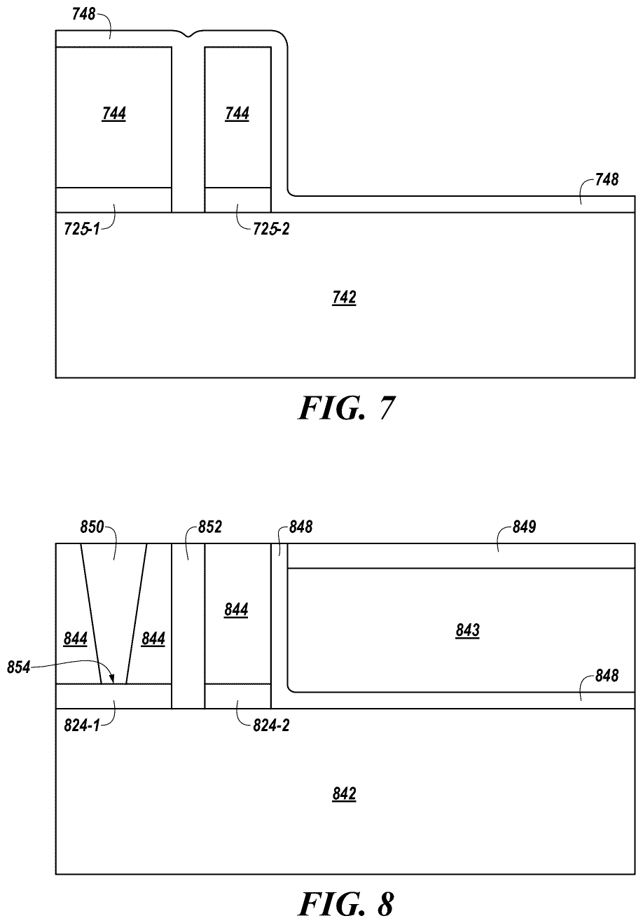

FIG. 8 illustrates a local interconnect digit line interface in an isolation region of a memory die in accordance with a number of embodiments of the present disclosure. FIG. 8 illustrates the digit line separated into a first portion 824-1 and a second portion 824-2 separated by spacer 852 after further processing steps. Also, FIG. 8 illustrates local interconnect digit line interface 854 at the intersection of the first portion of digit line 824-1 and the local interconnect region 850. Local interconnect region 850 can be coupled to sense amps that can be used during sensing operations on the array of memory cells. The conductive material is etched to form each of the digit lines 824 and dielectric material 843 is formed on dielectric material 848 and is annealed. Dielectric material 843 can be an oxide. The anneal process can cause erosion of the second portion of digit line 824-2 away from the dielectric material 843. Spacer 852 can stop the erosion of the second portion of the digit line 824-2 such that the second portion of the digit line 824-2 can act as a sacrificial material and the first portion of digit line 824-1 remains allowing the first portion of digit line 824-1 and local interconnect region 850 to form local interconnect digit line interface 854. Spacer 852 can be approximately 15-30 nanometers (nm) wide. The distance between spacer 852 and local interconnect digit line interface 854 can be approximately 15-30 nm and the distance between spacer 852 and dielectric material 848 can be approximately 40-60 nm.

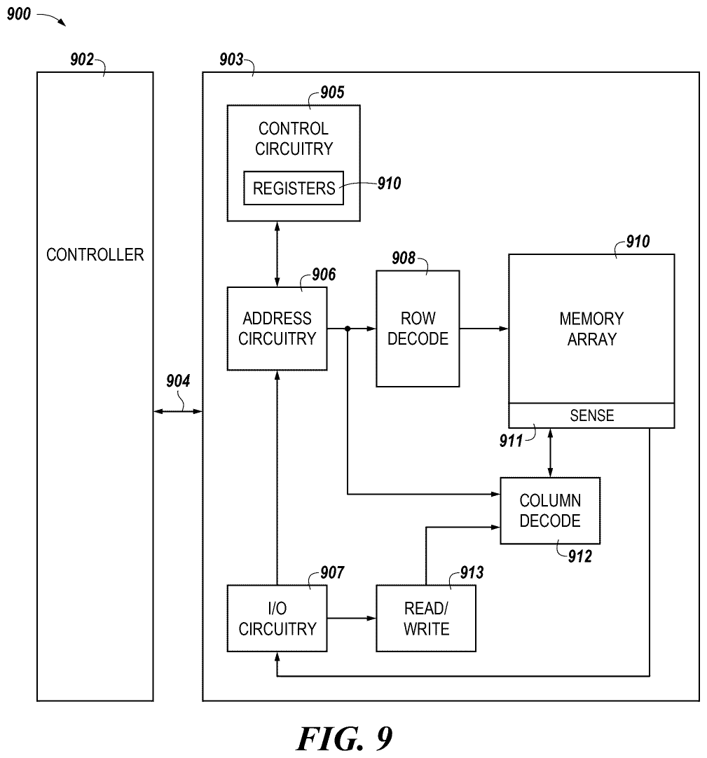

FIG. 9 is a block diagram of an apparatus in the form of a computing system 900 including a memory device 903 in accordance with a number of embodiments of the present disclosure. As used herein, a memory device 903, a memory array 910, and/or a host 902, for example, might also be separately considered an “apparatus.” According to embodiments, the memory device 902 may comprise at least one memory array 910 with a memory cell formed having a digit line and body contact, according to the embodiments described herein.

In this example, system 900 includes a host 902 coupled to memory device 903 via an interface 904. The computing system 900 can be a personal laptop computer, a desktop computer, a digital camera, a mobile telephone, a memory card reader, or an Internet-of-Things (IoT) enabled device, among various other types of systems. Host 902 can include a number of processing resources (e.g., one or more processors, microprocessors, or some other type of controlling circuitry) capable of accessing memory 903. The system 900 can include separate integrated circuits, or both the host 902 and the memory device 903 can be on the same integrated circuit. For example, the host 902 may be a system controller of a memory system comprising multiple memory devices 903, with the system controller 905 providing access to the respective memory devices 903 by another processing resource such as a central processing unit (CPU).

In the example shown in FIG. 9, the host 902 is responsible for executing an operating system (OS) and/or various applications (e.g., processes) that can be loaded thereto (e.g., from memory device 903 via controller 905). The OS and/or various applications can be loaded from the memory device 903 by providing access commands from the host 902 to the memory device 903 to access the data comprising the OS and/or the various applications. The host 902 can also access data utilized by the OS and/or various applications by providing access commands to the memory device 903 to retrieve said data utilized in the execution of the OS and/or the various applications.

For clarity, the system 900 has been simplified to focus on features with particular relevance to the present disclosure. The memory array 910 can be a DRAM array comprising at least one memory cell having a digit line and body contact formed according to the techniques described herein. For example, the memory array 910 can be a 4F² array. The array 910 can comprise memory cells arranged in columns coupled by word lines (which may be referred to herein as access lines or select lines) and rows coupled by digit lines (which may be referred to herein as sense lines or data lines). Although a single array 910 is shown in FIG. 9, embodiments are not so limited. For instance, memory device 903 may include a number of arrays 910 (e.g., a number of banks of DRAM cells).

The memory device 903 includes address circuitry 906 to latch address signals provided over an interface 904. The interface can include, for example, a physical interface employing a suitable protocol (e.g., a data bus, an address bus, and a command bus, or a combined data/address/command bus). Such protocol may be custom or proprietary, or the interface 904 may employ a standardized protocol, such as Peripheral Component Interconnect Express (PCIe), Gen-Z, CCIX, or the like. Address signals are received and decoded by a row decoder 908 and a column decoder 912 to access the memory array 910. Data can be read from memory array 910 by sensing voltage and/or current changes on the sense lines using sensing circuitry 911. The sensing circuitry 911 can comprise, for example, sense amplifiers that can read and latch a page (e.g., row) of data from the memory array 910. The I/O circuitry 907 can be used for bi-directional data communication with the host 902 over the interface 904. The read/write circuitry 913 is used to write data to the memory array 910 or read data from the memory array 910. As an example, the circuitry 913 can comprise various drivers, latch circuitry, etc.

Control circuitry 905 decodes signals provided by the host 902. The signals can be commands provided by the host 902. These signals can include chip enable signals, write enable signals, and address latch signals that are used to control operations performed on the memory array 910, including data read operations, data write operations, and data erase operations. In various embodiments, the control circuitry 905 is responsible for executing instructions from the host 902. The control circuitry 905 can comprise a state machine, a sequencer, and/or some other type of control circuitry, which may be implemented in the form of hardware, firmware, or software, or any combination of the three. In some examples, the host 902 can be a controller external to the memory device 903. For example, the host 902 can be a memory controller which is coupled to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

While example embodiments including various combinations and configurations of sensing circuitry, sense amplifiers, compute components, logic stripes, shared I/O lines, column select circuitry, multiplexers, latch components, latch stripes, and/or latches, etc., have been illustrated and described herein, embodiments of the present disclosure are not limited to those combinations explicitly recited herein. Other combinations and configurations of the sensing circuitry, sense amplifiers, compute components, logic stripes, shared I/O lines, column select circuitry, multiplexers, latch components, latch stripes, and/or latches, etc., disclosed herein are expressly included within the scope of this disclosure.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

As used herein, “a number of” or “a quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and coupled to each of the two elements.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” another element, the particular element can cover the other element, can be over the other element or lateral to the other element and/or can be in direct physical contact the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. An apparatus, comprising:
an array of memory cells, wherein each memory cell is coupled to a digit line, wherein a first spacer separates a first portion of the digit line from a second portion of the digit line, and wherein the first portion of the digit line is electrically coupled to a sense amplifier via a local interconnect digit line interface and the second portion of the digit line is not electrically coupled to the sense amplifier.

2. The apparatus of claim 1, wherein a first end of the first portion of the digit line is adjacent to the first spacer.

3. The apparatus of claim 2, wherein the first spacer is between the array of memory cells and a peripheral component region.

4. The apparatus of claim 3, wherein a second spacer separates the array of memory cells from the peripheral component region.

5. The apparatus of claim 1, wherein the local interconnect digit line interface is located at the first portion of the digit line and the second portion of the digit line is electrically isolated from the first portion of the digit line.

6. The apparatus of claim 3, wherein the peripheral component region includes CMOS logic circuitry.

7. An apparatus, comprising:
an array of memory cells, wherein
the memory cells each include an access device having a first source/drain region and a second source/drain region separated by a channel region and a gate opposing the channel region;
the memory cells each include a digit line contact at the second source/drain region and a storage node coupled to respective first source/drain regions; and
the memory cells each include a digit line coupled to the digit line contact, wherein a spacer is between a first portion of the digit line and a second portion of the digit line and wherein the first portion of the digit line is electrically coupled to a sense amplifier via a local interconnect digit line interface and the second portion of the digit line is not electrically coupled to the sense amplifier.

8. The apparatus of claim 7, wherein the spacer is located between an oxide region and the local interconnect digit line interface.

9. The apparatus of claim 7, wherein the spacer is configured to prevent the first portion of the digit line from eroding to maintain the local interconnect digit line interface.

10. The apparatus of claim 8, wherein the oxide region separates the array of memory cells from a peripheral component region.

11. The apparatus of claim 8, wherein the local interconnect digit line interface is formed where the first portion of the digit line is coupled to a local interconnect region.

12. The apparatus of claim 8, wherein the second portion of the digit line is between the spacer and the oxide region.

13. The apparatus of claim 12, wherein the second portion of the digit line erodes from a sidewall of the oxide region.

14. The apparatus of claim 13, wherein erosion of the second portion of the digit line from the sidewall of the oxide region is stopped by the spacer.

15. An apparatus, comprising:
an array of memory cells, wherein the array of memory cells include a number of digit lines; and
a peripheral component region, wherein the array of memory cells and the peripheral component region are separated by an isolation region, wherein a first portion of the number of digit lines form a number of local interconnect digit line interfaces within the isolation region, and wherein a spacer separates the number of local interconnect digit line interfaces from a second portion of the number of digit lines such that the first portion of the number of digit lines are electrically coupled to sense amps via a number of local interconnect digit line interfaces and the second portion of the number of digit lines are not electrically coupled to the sense amps.

16. The apparatus of claim 15, wherein the peripheral component region includes CMOS logic circuitry.

17. The apparatus of claim 15, wherein the spacer is a nitride spacer formed in the isolation region.

18. The apparatus of claim 15, wherein a first end of the second portion of the number of digit lines erodes from a sidewall of an oxide spacer in the isolation region.

19. The apparatus of claim 15, wherein erosion of the first end of the second portion of the number of digit lines from the sidewall of the oxide spacer is stopped by the spacer.

20. The apparatus of claim 15, wherein the memory cells are dynamic random access memory (DRAM) cells.
